(19) United States
(12) Patent Application Publication
(10) Pub. No.: US 2014/0346634 A1
(43) Pub. Date: Nov. 27, 2014

(54) ON-CHIP INDUCTORS WITH REDUCED AREA AND RESISTANCE

(71) Applicant: Synopsys, Inc., Mountain View, CA (US)

(72) Inventors: Junqi Hua, Portland, OR (US); David A. Yokoyama-Martin, Portland, OR (US)

(73) Assignee: Synopsys, Inc., Mountain View, CA (US)

(21) Appl. No.: 13/901,477

(22) Filed: May 23, 2013

(51) Int. Cl. G06F 17/50; H01L 23/522

(52) U.S. Cl. CPC G06F 17/5077; H01L 23/5227
USPC 257/531; 716/130

(57) ABSTRACT

An integrated circuit that includes an on-chip inductor wrapped around an interface pad. On-chip inductors are arranged around an interface pad to reduce the area occupied by the inductor. Furthermore, arranging the on-chip inductors in an upper level metal layer, such us the redistribution layer (RDL), the top metal interconnect layer (MTop), or the second-to-top metal interconnect layer (MTop-1) reduces the on-chip inductor parasitic resistance, reducing the loss of signal.

### BACKGROUND

1. Field of Art

This disclosure generally relates to the field of electronic design automation (EDA), and more specifically to minimizing the area and resistance of on-chip inductors in an integrated circuit.

2. Description of the Related Art

Parasitic capacitances are oftentimes present at the input or output of an electronic circuit. Parasitic capacitances may arise due to capacitances of metal wires or interconnects, the capacitance of interface pads, the capacitance of the termination devices, the capacitance of electrostatic discharge (ESD) protection diodes, capacitances of transistors in an electronic circuit, and the like. The parasitic capacitance present at the interface (e.g., input or output) of an electronic circuit increases the return loss at that interface, degrading the performance of the electronic circuit.

In order to reduce the return loss, an inductor can be inserted to compensate for the parasitic capacitance. On-chip inductors are oftentimes bulky, reducing the usable area for metal interconnects and routing of different signals throughout a chip. For instance, a 0.9 nH inductor needed to compensate a 0.6 pF capacitance may occupy an area of 60 μm×60 μm. Furthermore, the on-chip inductors added to compensate parasitic capacitances may introduce an additional parasitic resistance, which may reduce the signal magnitude delivered to the electronic circuit.

### SUMMARY

Embodiments relate to an on-chip inductor wrapped around an interface pad of an integrated circuit. On-chip inductors are configured to route a signal to or from an electronic circuit and can compensate for the parasitic capacitance of the electronic circuit. Furthermore, the on-chip inductor may be formed in an upper level metal layer, such as the redistribution layer (RDL), the top level metal interconnect layer (MTop), or the second-to-top level metal interconnect layer (MTop-1).

In one embodiment, the on-chip inductor is wrapped around a flip chip pad, shaped as an octagon. In other embodiment, the on-chip inductor is wrapped around a wire bond pad, shaped as a square.

In some embodiments, the on-chip inductor may be a two terminal inductor with one terminal coupled to the interface pad, and the other terminal coupled to the electronic circuit. In another embodiment, the inductor may be a T-coil type inductor with one terminal coupled to the interface pad, a second terminal coupled to a resistor, and a third terminal coupled to the electronic circuit.

### BRIEF DESCRIPTION OF DRAWINGS

The disclosed embodiments have other advantages and features which will be more readily apparent from the detailed description, the appended claims, and the accompanying figures (or drawings). A brief introduction of the figures is below.

FIG. 1 illustrates a computer system for executing an electronic design automation (EDA) processes, according to one embodiment.

FIG. 2 is a flowchart illustrating various operations in the design and fabrication of an integrated circuit, according to one embodiment.

FIG. 3A is a block diagram illustrating an integrated circuit interface where the input capacitance is negligible.

FIG. 3B is a block diagram illustrating an integrated circuit interface where the input capacitance is not negligible.

FIG. 3C is a block diagram illustrating an integrated circuit interface using a T-coil inductor.

FIG. 4A is a plan view of an integrated circuit pad assembly, according to one embodiment.

FIG. 4B is a plan view illustrating an interface assembly with an octagonal shape, according to one embodiment.

FIG. 4C is plan view illustrating an interface assembly with a rectangular shape, according to another embodiment.

FIG. 4D is a cross sectional view illustrating an interface assembly, according to one embodiment.

FIG. 5 is a flowchart illustrating a process for communicating signals to and from an integrated circuit, according to one embodiment.

FIG. 6 is a flowchart illustrating a process for generating a representation of an integrated circuit (IC), according to one embodiment.

### DETAILED DESCRIPTION

The Figures (FIGS.) and the following description relate to preferred embodiments by way of illustration only. It should be noted that from the following discussion, alternative embodiments of the structures and methods disclosed herein will be readily recognized as viable alternatives that may be employed without departing from the principles of what is claimed.

Reference will now be made in detail to several embodiments, examples of which are illustrated in the accompanying figures. It is noted that wherever practicable similar or like reference numbers may be used in the figures and may indicate similar or like functionality. The figures depict embodiments of the disclosed system (or method) for purposes of illustration only. Alternative embodiments of the structures and methods illustrated herein may be employed without departing from the principles described herein.

Embodiments of the present disclosure relate to wrapping an on-chip inductor around an interface pad of an integrated circuit using an upper level metal layer. By wrapping the inductor around the interface pad, the area occupied by the inductor can be reduced. Further, by using an upper level metal layer to implement the inductor, the parasitic resistance of the on-chip inductor can be reduced. Integrated circuits contain metal layers that are used to form different structures such as interconnects, interface pads, capacitors, etc. Embodiments use one or more of these metal layers to form on-chip inductors in the integrated circuits.

An on-chip inductor as described herein refers to an inductor integrated or fabricated in an integrated circuit. On-chip inductors are be formed by patterning metal coils in one or more metal layers in an integrated circuit. On-chip inductors are found in many electronic circuits, such as radio frequency (RF) circuits and serializer/deserializer (SerDes) circuits, where they can be used to compensate for parasitic capacitance.

### Computing Machine Architecture

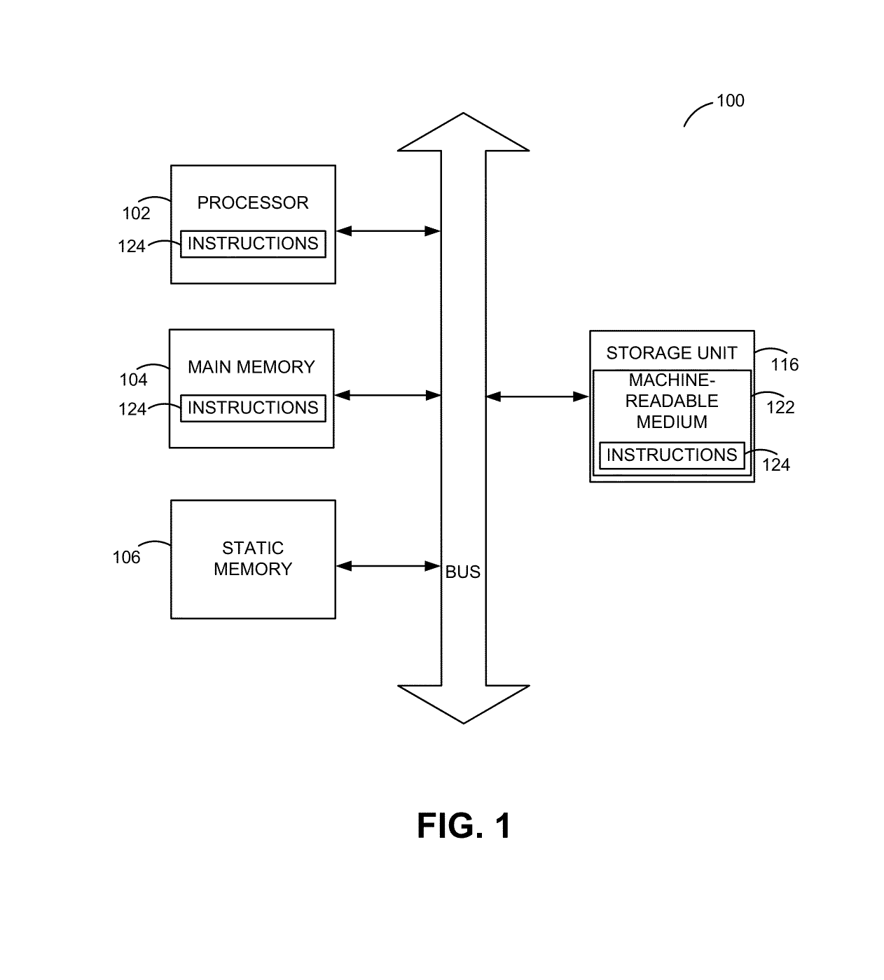

FIG. 1 is a block diagram of a computer system 100 for executing electronic design automation (EDA) processes, according to one embodiment. Specifically, FIG. 1 shows a diagrammatic representation of a machine in the example form of a computer system 100 within which instructions 124 (e.g., software) for causing the machine to perform any one or more of the EDA processes discussed herein may be executed. The computer system 100 operates as a standalone device or may be connected (e.g., networked) to other machines. In a networked deployment, the computer system 100 may operate in the capacity of a server machine or a client machine in a server-client network environment, or as a peer machine in a peer-to-peer (or distributed) network environment.

The example computer system 100 includes a processor 102 (e.g., a central processing unit (CPU), a graphics processing unit (GPU), a digital signal processor (DSP), one or more application specific integrated circuits (ASICs), a main memory 104, a static memory 106, and a storage unit 116 which are configured to communicate with each other via a bus 108. The storage unit 116 includes a machine-readable medium 122 on which is stored instructions 124 (e.g., software) embodying any one or more of the methodologies or functions described herein. The instructions 124 (e.g., software) may also reside, completely or at least partially, within the main memory 104 or within the processor 102 (e.g., within a processor's cache memory) during execution thereof by the computer system 100, the main memory 104 and the processor 102 also constituting machine-readable media.

While machine-readable medium 122 is shown in an example embodiment to be a single medium, the term “machine-readable medium” should be taken to include a single medium or multiple media (e.g., a centralized or distributed database, or associated caches and servers) able to store instructions (e.g., instructions 124). The term “machine-readable medium” shall also be taken to include any medium that is capable of storing instructions (e.g., instructions 124) for execution by the machine and that cause the machine to perform any one or more of the methodologies disclosed herein. The term “machine-readable medium” includes, but not be limited to, data repositories in the form of solid-state memories, optical media, and magnetic media.

### Overview of EDA Design Flow

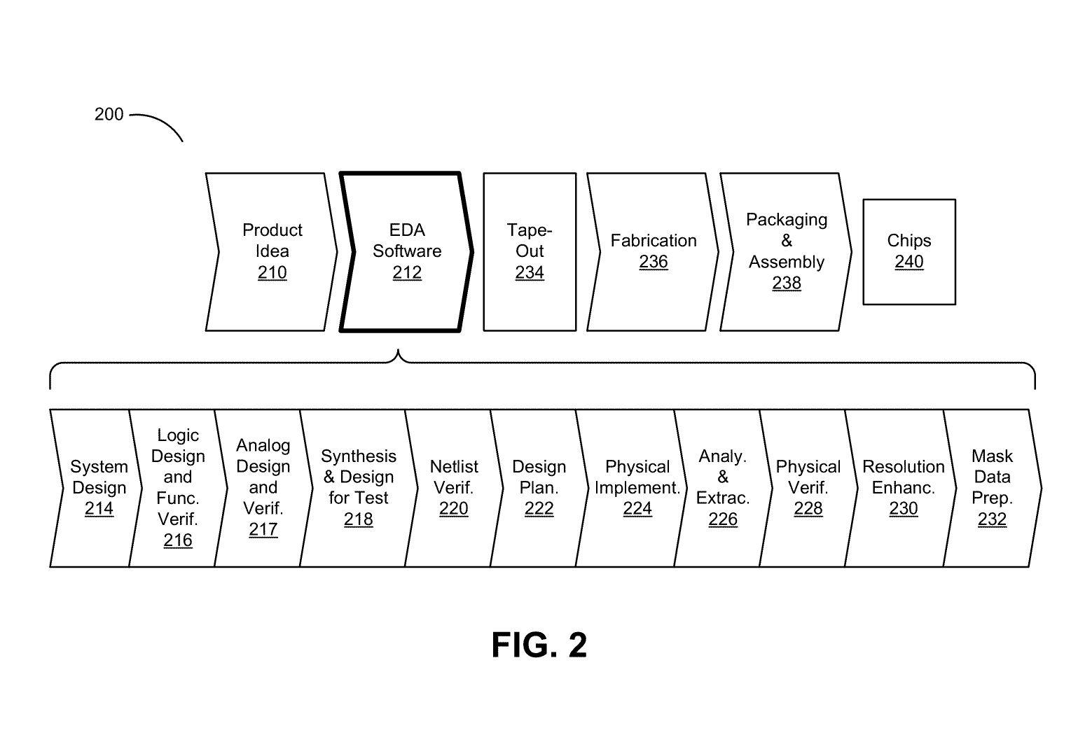

FIG. 2 is a flowchart 200 illustrating the various operations in the design and fabrication of an integrated circuit. This process starts with the generation of a product idea 210, which is realized during a design process that uses electronic design automation (EDA) software 212. When the design is finalized, it can be taped-out 234. After tape-out, a semiconductor die is fabricated 236 to form the various objects (e.g., gates, metal layers, vias) in the integrated circuit design. Packaging and assembly processes 238 are performed, which result in finished chips 240.

The EDA software 212 may be implemented in one or more computing devices such as the computer 100 of FIG. 1. For example, the EDA software 212 is stored as instructions in the computer-readable medium which are executed by a processor for performing operations 214-232 of the design flow, which are described below. This design flow description is for illustration purposes. In particular, this description is not meant to limit the present disclosure. For example, an actual integrated circuit design may require a designer to perform the design operations in a difference sequence than the sequence described herein.

During system design 214, designers describe the functionality to implement. They can also perform what-if planning to refine the functionality and to check costs. Note that hardware-software architecture partitioning can occur at this stage. Example EDA software products from Synopsys, Inc. of Mountain View, Calif. that can be used at this stage include: Model Architect®, Saber®, System Studio®, and Designware® products.

During logic design and functional verification 216, VHDL or Verilog code for modules in the circuit is written and the design is checked for functional accuracy. More specifically, the design is checked to ensure that it produces the correct outputs. Example EDA software products from Synopsys, Inc. of Mountain View, Calif. that can be used at this stage include: VCS®, Vera®, 10 Designware®, Magellan®, Formality®, ESP® and Leda® products.

During analog design, layout, and simulation 217, analog circuits are designed, layed out, and simulated to ensure both functionality and performance. Example EDA software products from Synopsys, Inc. of Mountain View, Calif. that can be used at this stage include: Custom Designer®, Hspice®, HspiceRF®, XA®, Nanosim®, HSim®, and Finesim® products.

During synthesis and design for test 218, VHDL/Verilog is translated to a netlist. This netlist can be optimized for the target technology. Additionally, tests can be designed and implemented to check the finished chips. Example EDA software products from Synopsys, Inc. of Mountain View, Calif. that can be used at this stage include: Design Compiler®, Physical Compiler®, Test Compiler®, Power Compiler®, FPGA Compiler®, Tetramax®, and Designware® products.

During netlist verification 220, the netlist is checked for compliance with timing constraints and for correspondence with the VHDL/Verilog source code. Example EDA software products from Synopsys, Inc. of Mountain View, Calif. that can be used at this stage include: Formality®, Primetime®, and VCS® products.

During design planning 222, an overall floor plan for the chip is constructed and analyzed for timing and top-level routing. Example EDA software products from Synopsys, Inc. of Mountain View, Calif. that can be used at this stage include: Astro® and IC Compiler® products.

During physical implementation 224, the placement (positioning of circuit elements) and routing (connection of the same) occurs. Example EDA software products from Synopsys, Inc. of Mountain View, Calif. that can be used at this stage include: the Astro® and IC Compiler® products.

During analysis and extraction 226, the circuit function is verified at a transistor level, which permits refinement. Example EDA software products from Synopsys, Inc. of Mountain View, Calif. that can be used at this stage include: Astrorail®, Primerail®, Primetime®, and Star RC/XT® products.

During physical verification 228, the design is checked to ensure correctness for: manufacturing, electrical issues, lithographic issues, and circuitry. Example EDA software products from Synopsys, Inc. of Mountain View, Calif. that can be used at this stage include the Hercules® product.

During resolution enhancement 230, geometric manipulations of the layout are performed to improve manufacturability of the design. Example EDA software products from Synopsys, Inc. of Mountain View, Calif. that can be used at this stage include: Proteus®, Proteus®AF, and PSMGED® products.

During mask-data preparation 232, the ‘tape-out’ data for production of masks to produce finished chips is provided. Example EDA software products from Synopsys, Inc. of Mountain View, Calif. that can be used at this stage include the CATS® family of products.

Embodiments of the present disclosure can be used during one or more of the above-described stages. Specifically, embodiments may be used for the processes of design planning 222 and physical implementation 224.

Overview of on-Chip Inductor

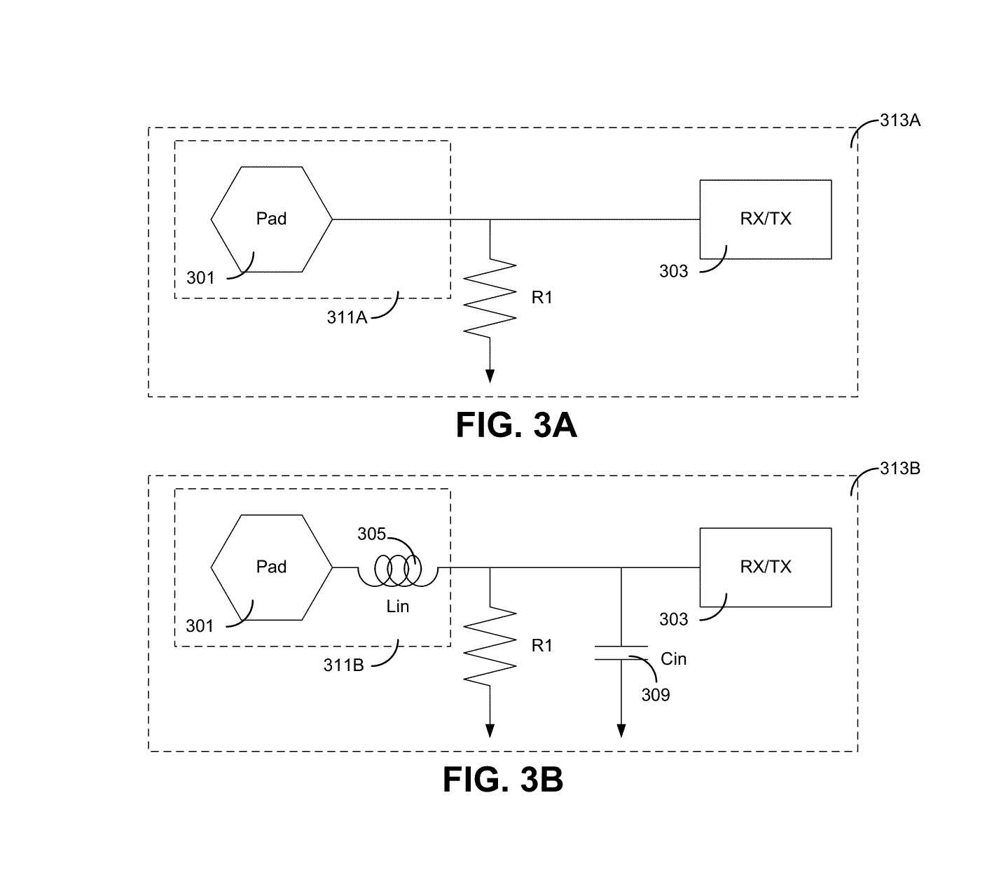

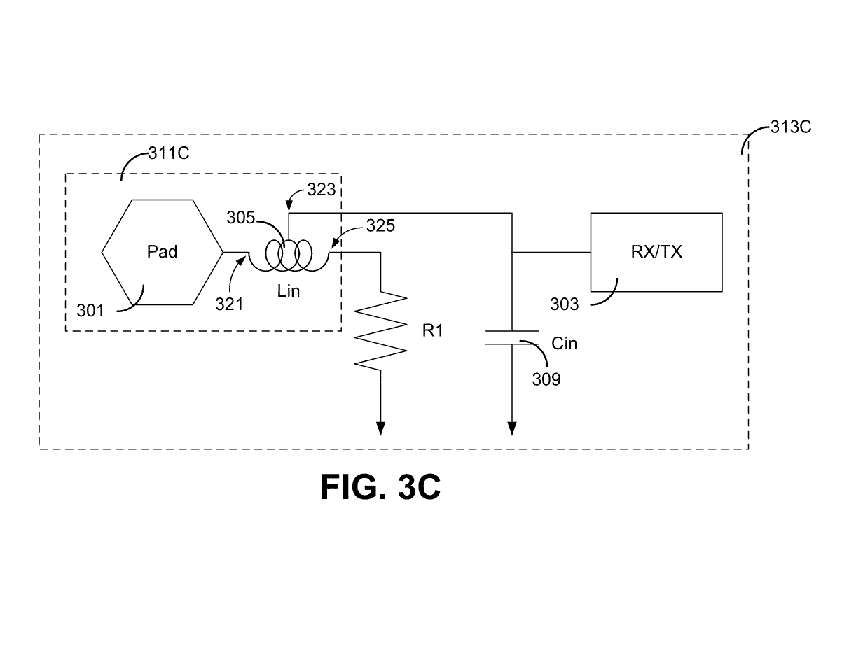

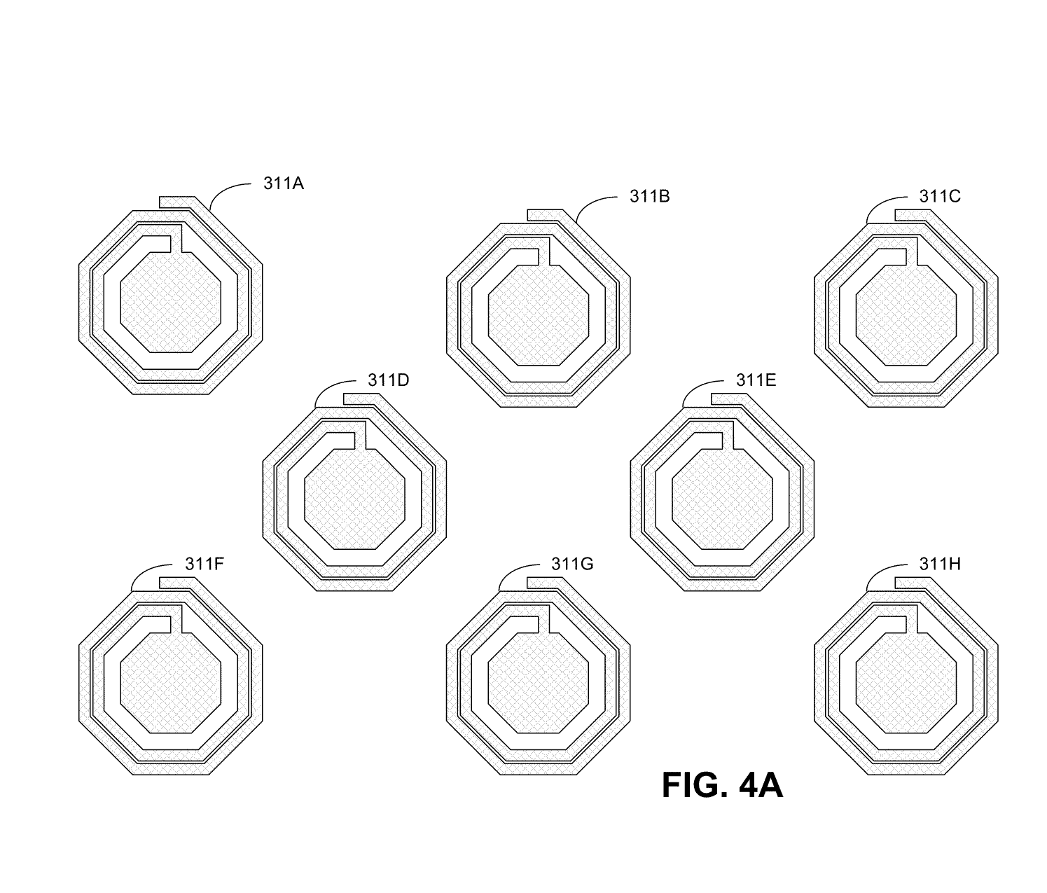

FIGS. 3A, 3B, and 3C are block diagrams of an integrated circuit interface. In order to interact with external components, each of integrated circuits 313A through 313C includes an interface pad 301. Although only one interface pad 301 is illustrated in FIGS. 3A, 3B, and 3C, each of the integrated circuits 313A through 313C may include multiple interface pads. The interface pad 301 is coupled to inputs and/or outputs of an electronic circuit 303 that transmits or receives signals via a signal path between the interface pad 301 and the electronic circuit 303. Although in FIGS. 3A and 3B, the electronic circuit 303 is represented by a receiver/transmitter (Rx/Tx) circuit, the electronic circuit 303 is not limited to Rx/Tx circuits, and it may be any electronic circuit that interfaces with external devices.

An interface pad 301 may interface with external circuitry using different conductive elements. For example, a wire bond pad may interface with external circuitry using thin metal wires attached to the interface pad 301. The metal wires are attached to the interface pad 301 via a wire bonding technique, such as thermosonic bonding. Alternatively, flip chip pads may interface with external circuitry using small solder balls that are placed on top of the flip chip pad. The small solder balls are attached to the external circuitry through a reflow process.

The shape and the location of the interface pads 301 may differ based on the conductive elements used for interfacing with the external circuitry. For instance, a wire bond pad may be located around the perimeter of the die and may have a square or rectangular shape whereas a flip chip pad may be located periodically throughout the top surface of die and may have an octagonal shape. In some embodiments, to increase the yield in fabrication and reduce the number of defects, the shape, size and/or location of interface pads are specified by the fabrication facility (fab). For example, a fab may specify that each die should contain 40 wire bond pads with 10 pads located at each side of the die. Each pad would be shaped as a square and would have a size of 45 μm×45 μm. In other embodiment, the fab may specify a set of minimum requirements for the interface pads while allowing some flexibility on the shape, size, and/or location of the interface pads.

The electronic circuit 303 interfaces with external circuitry to perform various functions. Examples of electronic circuits 303 include receivers, transmitters, input/output buffers, and the like. The electronic circuit 303 may be a complementary metal-oxide-semiconductor (CMOS) circuit, a bipolar junction transistor (BJT) circuit, a BiCMOS circuit, monolithic microwave integrated circuits (MMIC), and the like.

The input capacitance 309 is the capacitance seen at the input of the electronic circuit 303. The input capacitance 309 may be caused by the capacitance of the metal wires or interconnects, the capacitance of the interface pad, the capacitance of the termination devices, the capacitance of electrostatic discharge (ESD) protection diodes, capacitances in the electronic circuit 303, and the like. If the input capacitance 309 at the interface of the electronic circuit 303 is substantially zero or negligible, then the interface pad 301 may be directly connected to the interface of the electronic circuit 303, as shown in FIG. 3A, since additional circuitry is not needed to reduce the reactance present at the interface of the electronic circuit 303. The input capacitance 309 is considered to be negligible if the return loss experienced due to the input capacitance 309 is lower than the maximum tolerable return loss, as specified by the requirements of the electronic circuit 303. If the input capacitance 309 at the interface of the electronic circuit 303 is not negligible, then an input inductor 305 may be needed to compensate the input capacitance 309, as shown in FIG. 3B.

In the embodiment of FIG. 3B, the inductor 305 is a two terminal inductor with one terminal coupled to the interface pad 301 and the other terminal coupled to the electronic circuit 303. In the embodiment of FIG. 3C, the inductor 305 is a T-coil inductor with one terminal 321 connected to the interface pad 301, a second terminal 323 connected to the electronic circuit 303, and a third terminal 325 coupled to a resistor. The use of inductor 305 increases the resistance in the signal path between the electronic circuit 303 and the interface pad 301, causing the attenuation of a signal traveling along this signal path. Such attenuation of the signal may degrade the performance of the circuit 303.

### Redistribution Layer (RDL) Inductors

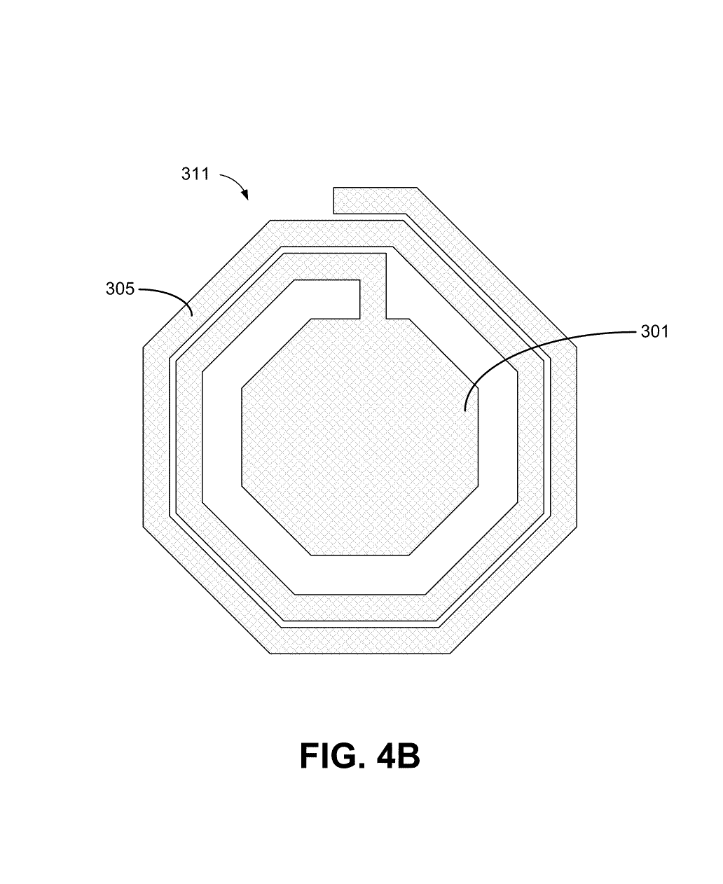

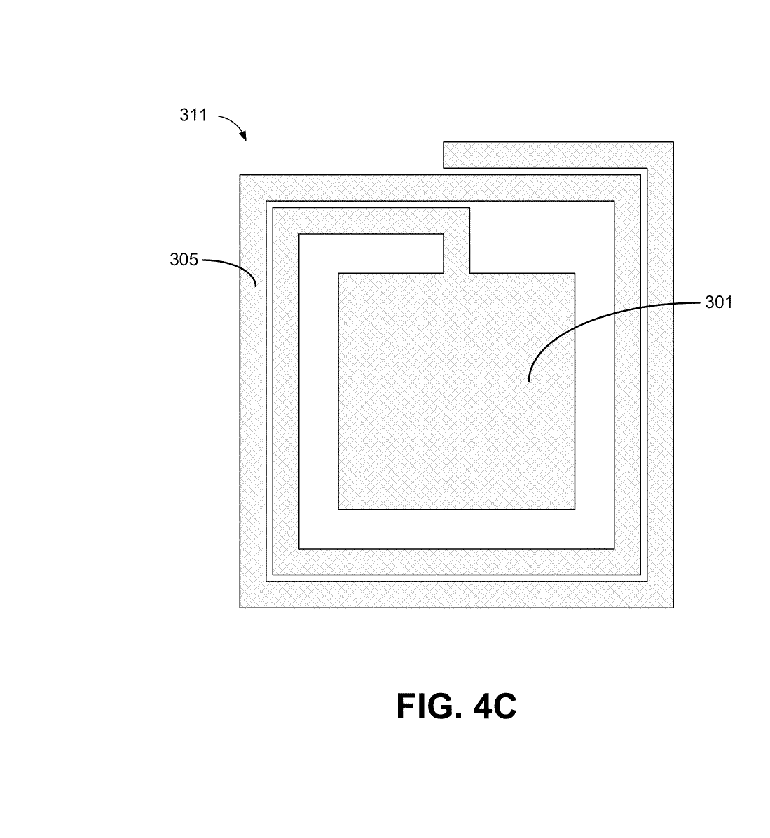

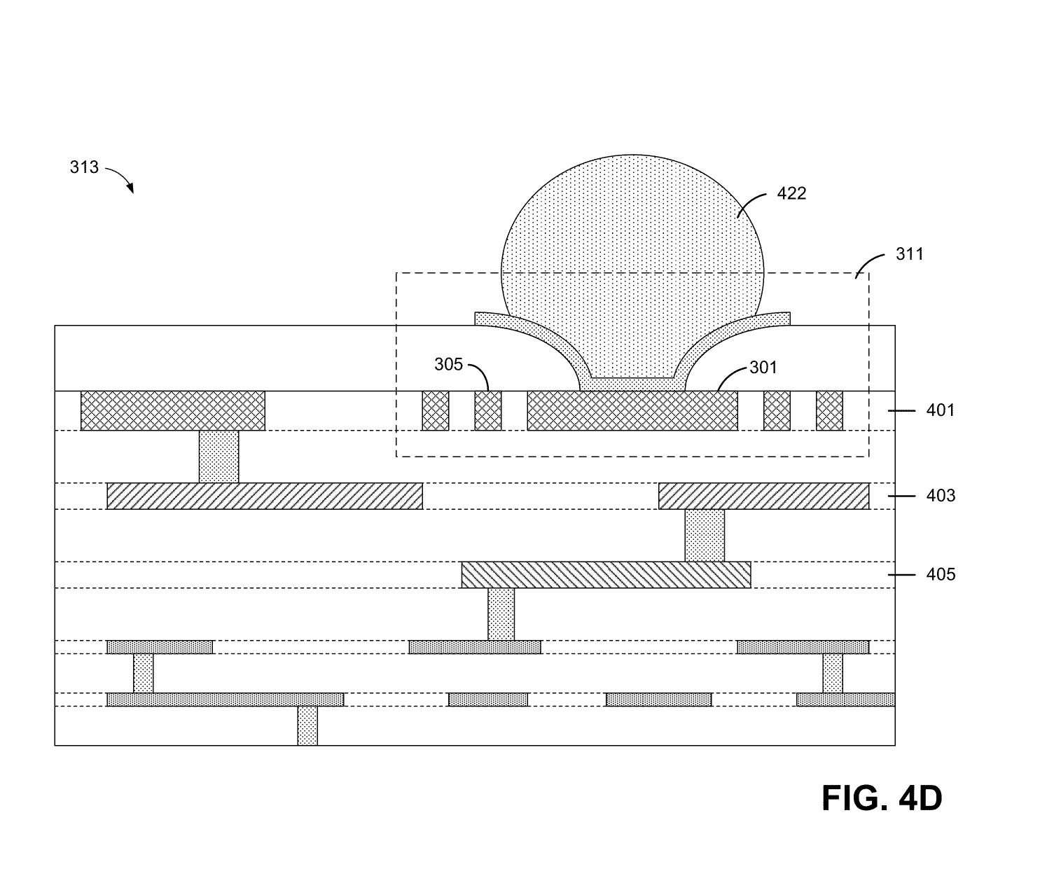

FIG. 4A illustrates one embodiment of an integrated circuit pad assembly. Although only eight interface pads 311A through 311H (hereinafter collectively referred to as “interface pads 311”) are shown in FIG. 4A, a typical integrated circuit 313 may contain tens or even hundreds of interface pads to receive or transmit signals in or out of the integrated circuit 313. In conventional integrated circuit manufacturing, interface pads are formed in a metal layer called the redistribution layer RDL (also sometimes called the AP or RV layer). RDL is the uppermost metal layer in the fabrication of an integrated circuit and is several times thicker (e.g., 10 times thicker) than other metal layers. As a result, metal traces fabricated in the RDL are several times more conductive (e.g., 10 times more conductive) than metal traces or interconnects fabricated in lower metal layers.

In order to increase the manufacturing yield and decrease the likelihood of shorting of wire bonds used in wire bond pads or micro balls used in flip chip pads, the interface pads are separated from each other by a distance larger than the minimum metal-to-metal separation, as specified by the fab. The minimum metal-to-metal separation may be needed due to limitations of the lithography equipment used to pattern the metal region. For example, the minimum metal-to-metal separation in the RDL layer for the 28 nm technology node is about 2 μm, while the separation between two flip chip pads for the same technology node is about 95 μm, leaving a large area of the RDL layer unused. This unused area can then be used to form the inductor 305 for compensating parasitic input capacitance 309.

FIGS. 4B and 4C are plan views illustrating two embodiments of the interface assembly 311. FIG. 4B illustrates an embodiment of the interface assembly 311 with an octagonal shape, such as the ones used as flipped chip pads; and FIG. 4C illustrates an embodiment of the interface assembly 311 with a rectangular shape, such as the ones used as wire bond pads.

As illustrated in FIG. 4B and FIG. 4C, the interface assembly 311 comprises an interface pad 301 and an on chip inductor 305. As described above, the interface pad 301 is formed in the upper most metal layer oftentimes called RDL and its characteristics are usually specified by the fabrication facility. In order to reduce the space occupied by the inductor 305 and to reduce the parasitic resistance of the inductor 305, the inductor 305 may also be formed in the RDL metal layer. As illustrated in FIG. 4B and FIG. 4C, the inductor 305 wraps around the interface pad 301, running along the contour of the interface pad 301. In one embodiment, the length of the inductor 305, or the number of times the inductor 305 wraps around the interface pad 301 is based on the parasitic capacitance the inductor 305 compensates. In other embodiments, the length of the inductor 305, or the number of times the inductor 305 wraps around the interface pad 301 is specified by the fab and is uniform across all interface assemblies 311.

In some embodiments, the inductor 305 may also be formed in the top level metal interconnect layer (MTop) or the second-to-top level metal interconnect layer (MTop-1). MTop and MTop-1 are commonly used for global routing such as power distribution. The MTop and MTop-1 metal layers are thicker than lower level metal interconnect layer, reducing the parasitic resistance of the inductor 305.

FIG. 4D is a cross sectional view of the upper metal layer in an integrated circuit 313 that includes an interface assembly 311. Even though the on-chip inductor 305 is shown to be formed in the RDL layer 401, as described above, the on-chip inductor may also be formed in other upper level metal layers such as MTop 403 and MTop-1 405. When the on-chip inductor is formed in MTop 403 or MTop-1 405, a via may be used to connect the on-chip inductor to a solder ball 422.

### Method of Operation

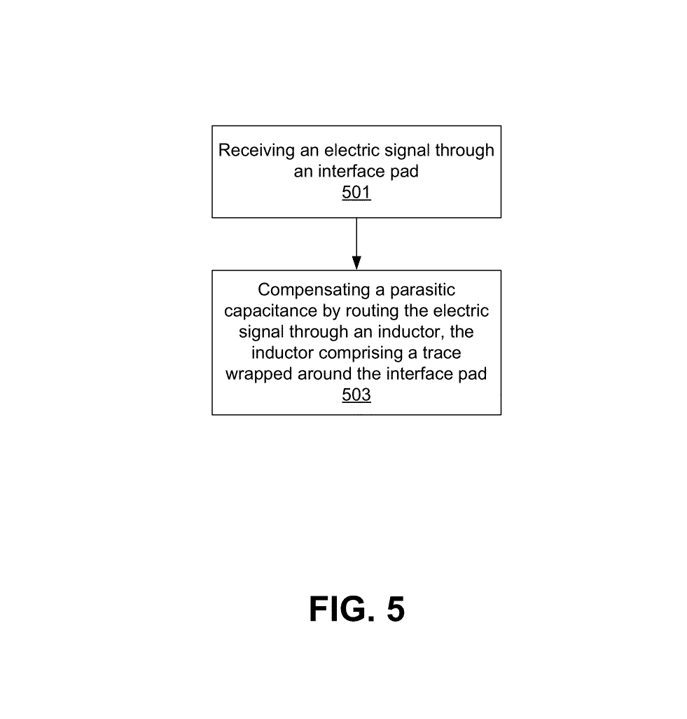

FIG. 5 is one embodiment of a method for communicating signals to and from an integrated circuit. An electric signal is received 501 through an interface pad 301. A parasitic capacitance 309 present at the input of the electronic circuit 303 is compensated 503 by routing the electric signal through an inductor 305 to the electronic circuit 303. In some embodiments, the inductor 305 comprises a metal trace formed in the redistribution metal layer (RDL) that wraps around the interface pad 301. In other embodiments, the metal trace is formed in other metal layers such as the top metal interconnect layer (MTop) or the second-to-top metal interconnect layer (MTop-1).

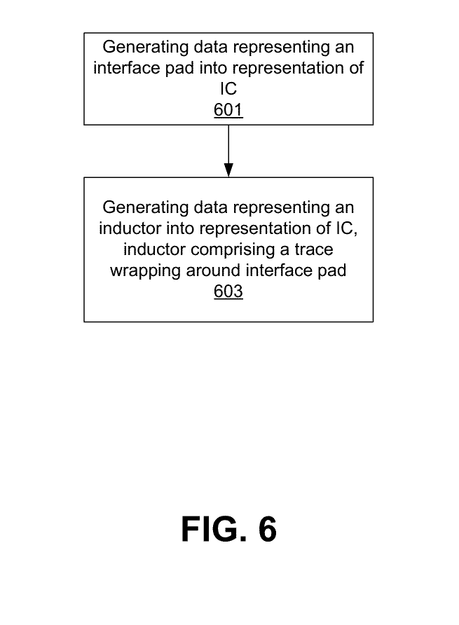

FIG. 6 is one embodiment of a method for generating a representation of an integrated circuit (IC). In one embodiment, the method is performed by the EDA software 212 during design planning 222, physical implementation 224, or analysis and extraction 226. In one embodiment of the method, the EDA software 212 generates a representation of an interface pad 301 in the RDL layer of the integrated circuit.

The EDA software 212 generates 603 a representation of the inductor 305. The representation of the inductor 305 comprises representation of a metal trace in an upper level metal layer, such as the redistribution layer (RDL), the top level metal interconnect layer (MTop) or the second-to-top metal interconnect layer (MTop-1).

In some embodiments, the EDA software 212 determines the capacitance 309 to be compensated by the inductor 305 may be determined by a parasitic extraction such as the one performed by the analysis and extraction 226 step of the EDA software 212. After extraction of the parasitic, the capacitance present at the input of the electronic circuit 303 may be determined and the inductance needed to compensate that capacitance may be calculated.

The representation of the integrated circuit is then output, which can include storing the layout to a non-transitory computer readable medium. In one embodiment, the representation of the integrated circuit can be provided to a foundry that fabricates the integrated circuit by forming the gates in the layout and cutting the gates at the locations of the cut-gate features.

Upon reading this disclosure, those of skill in the art will appreciate still additional alternative structural and functional designs for an on-chip inductor architecture for reducing the area and resistance of the inductor through the disclosed principles herein. Thus, while particular embodiments and applications have been illustrated and described, it is to be understood that the disclosed embodiments are not limited to the precise construction and components disclosed herein. Various modifications, changes and variations, which will be apparent to those skilled in the art, may be made in the arrangement, operation and details of the method and apparatus disclosed herein without departing from the spirit and scope defined in the appended claims.

What is claimed is:

1. An integrated circuit comprising:
an electronic circuit;
an interface pad configured to communicate electric signals between the electronic circuit and an external circuit; and
an inductor connected to the interface pad, the inductor configured to route the electric signals to or from the electronic circuit, and comprising a trace connected to the interface pad, the trace wrapped around the interface pad and formed in a metal layer selected from the group consisting of a redistribution metal layer (RDL), a top level metal interconnect layer (MTop), and a second-to-top level metal interconnect layer (MTop-1).

2. The integrated circuit of claim 1, wherein the metal trace is wrapped around the interface pad running around the contour of the interface pad.

3. The integrated circuit of claim 1, wherein the interface pad comprises a flip chip pad shaped as an octagon.

4. The integrated circuit of claim 1, wherein the interface pad comprises a wire bond pad shaped as a square.

5. The integrated circuit of claim 1, wherein the inductor is a T-coil inductor comprising:
a first terminal located at a first end of the T-coil inductor and coupled to the interface pad;
a second terminal located at a center of the T-coil inductor and coupled to ground; and
a third terminal located at a second end of the T-coil inductor and coupled to the electronic circuit.

6. A method for communication of signals to and from an integrated circuit comprising:
coupling an electronic circuit to an external circuit via an interface pad; and
compensating a parasitic capacitance of the electronic circuit by routing the electric signal to or from the electronic circuit via a trace, the trace wrapped around the interface pad and formed in a metal layer selected from the group consisting of a redistribution metal layer (RDL), a top level metal interconnect layer (MTop), and a second-to-top level metal interconnect layer (MTop-1).

7. A non-transitory computer readable medium storing a representation of an integrated circuit (IC), the representation comprising:
an electronic circuit;
an interface pad configured to communicate electric signals between the electronic circuit and an external circuit; and
an inductor connected to the interface pad, the inductor configured to route the electric signals to or from the electronic circuit, and comprising a trace connected to the interface pad, the trace wrapped around the interface pad and represented in a metal layer selected from the group consisting of a redistribution metal layer (RDL), a top level metal interconnect layer (MTop), and a second-to-top level metal interconnect layer (MTop-1).

8. The non-transitory computer readable medium of claim 7, wherein the metal trace wraps around the interface pad following the contour of the interface pad.

9. The non-transitory computer readable medium of claim 7, wherein the interface pad is a flip chip pad and is shaped as an octagon.

10. The non-transitory computer readable medium of claim 7, wherein the interface pad is a wire bond pad and is shaped as a square.

11. The non-transitory computer readable medium of claim 7, wherein the inductor is a T-coil inductor comprising:
a first terminal located at a first end of the T-coil inductor and coupled to the interface pad;
a second terminal located at a center of the T-coil inductor and coupled to ground; and
a third terminal located at a second end of the T-coil inductor and coupled to the electronic circuit.

12. A computer implemented method for generating a representation of an integrated circuit (IC), comprising:
generating first data representing an interface pad in a redistribution metal layer (RDL) of the integrated circuit; and
generating second data representing an inductor connected to the interface pad, the second data comprising a trace connected to the interface pad, the trace wrapped around the interface pad and arranged in a metal layer selected from the group consisting of the redistribution metal layer (RDL), a top level metal interconnect layer (MTop), and a second-to-top metal interconnect layer (MTop-1).

13. The computer implemented method of claim 12, further comprising determining a length of the trace based on a parasitic capacitance the inductor compensates.

14. The computer implemented method of claim 12, further comprising determining a number of times the trace loops around the interface pad based on a parasitic capacitance the inductor compensates.

15. The computer implemented method of claim 12, wherein the metal trace wraps around the interface pad following the contour of the interface pad.

16. The computer implemented method of claim 12, wherein the interface pad is a flip chip pad and is shaped as an octagon.

17. The computer implemented method of claim 12, wherein the interface pad is a wire bond pad and is shaped as a square.

18. The computer implemented method of claim 12, wherein the inductor is a T-coil inductor comprising:
a first terminal located at a first end of the T-coil inductor and coupled to the interface pad;
a second terminal located at a center of the T-coil inductor and coupled to ground; and
a third terminal located at a second end of the T-coil inductor and coupled to the electronic circuit.

19. The computer implemented method of claim 12, further comprising:
generating third data representing an electronic circuit;
determining a parasitic capacitance seen at an interface of the electronic circuit; and
determining an inductance of the inductor based on the determined capacitance.
